(19) United States
(12) Patent Application Publication
(10) Pub. No.: US 2005/0077547 A1
(43) Pub. Date: Apr. 14, 2005

(54) Method of fabricating a metal oxide semiconductor field effect transistor and a metal oxide semiconductor field effect transistor

(76) Inventors: Reiner Jumpertz, Freising (DE); Gottfried Hoffleisch, Roehrmoos (DE)

Correspondence Address: TEXAS INSTRUMENTS INCORPORATED, P O BOX 655474, M/S 3999, DALLAS, TX, 75265, US

(21) Appl. No.: 10/947,770

(22) Filed: Sep. 23, 2004

(30) Foreign Application Priority Data
Sep. 29, 2003 (DE) 103 451 86.2

(51) Int. Cl. H01L 29/745

(52) U.S. Cl. 257/213

(57) ABSTRACT

A method of fabricating a Metal Oxide Semiconductor Field Effect Transistor (MOSFET) is provided which comprises the steps of forming upon a semiconductor substrate (10) a field effect transistor structure comprising a gate oxide (12), a gate electrode (14) formed upon said gate oxide (12), a drain region (16) and a source region (18) which are formed within the semiconductor substrate (10) adjacent to the gate electrode (14), and depositing a fluorine in-situ doped insulating layer (28) covering the field effect transistor structure. The fluorine in-situ doped insulating layer (28) is provided for improving the transistor reliability.

### FIELD OF THE INVENTION

The present invention relates to a method of fabricating a Metal Oxide Semiconductor Field Effect Transistor (MOSFET). The present invention further relates to a Metal Oxide Semiconductor Field Effect Transistor (MOSFET).

### BACKGROUND OF THE INVENTION

In order to maintain or increase competitiveness in the international marketplace, it is a principal aim of IC manufacturers to reduce the costs which have to be expended in implementing a specific electronic function thereby increasing the productivity. This increase in productivity is achieved on the one hand by steadily increasing the diameter of the wafers upon which the electronic devices are formed (e.g. from a wafer diameter of 200 mm to a wafer diameter of 300 mm), and on the other hand by decreasing the feature size of the devices thus increasing the gross number of devices per wafer.

Reducing the feature size of a MOSFET leads, among other things, to a narrowing of the gate electrode dimensions and to a thinning of the gate oxide layer located beneath this narrow gate electrode. Unfortunately, decreasing of these dimensions gives rise to several degradation mechanisms which have a detrimental effect on the electrical parameters of the MOSFET device. One of these degradation mechanisms is the so-called Hot Carrier Effect (HCE). The HCE derives from increased electrical fields within advanced MOSFETs resulting from maintaining constant MOSFET operating voltages while decreasing the channel length of the transistor. Due to the increased electrical field the electrons which have enough kinetic energy can be injected from the semiconductor substrate upon which the MOSFET is formed into the gate oxide layer, where these so-called hot electrons may become trapped or may damage the substrate-oxide interface by creating traps that shift the threshold voltage and degrade the electron mobility. In a long term, these degradation mechanisms can cause the fail of the transistor thus reducing its reliability.

Known methods for improving the reliability of the circuits use. implanting of fluorine atoms. However, for activating the implanted fluorine atoms high activation energies are needed which makes difficult keeping control of the fluorine diffusion and which can have a negative impact on existing device structures. In addition, the amount of fluorine which can be incorporated by implanting technologies is not enough to improve the transistor reliability.

### SUMMARY OF THE INVENTION

The present invention provides a method of fabricating a Metal Oxide Semiconductor Field Effect Transistor (MOSFET) which can be easily integrated into existing process flows and by means of which the reliability of the transistor is enhanced.

According to the present invention a fluorine in-situ doped insulating layer is deposited which covers the field effect transistor structure. The in-situ doped insulation layer can be deposited by using conventional deposition tools, e.g. by using a conventional CVD (Chemical Vapor Deposition) reactor, and offers a very high source of fluorine atoms. Activation of the in-situ incorporated fluorine does not require high activation energies so that the deposition step can be implemented in a late stage of the process flow without having any negative impact on existing structures.

According to a preferred variant of the method depositing of the fluorine in-situ doped layer terminates a sequence of process Front End Of Line (FEOL) process steps. Usually, after creating the gate electrode and defining the source/drain regions an undoped liner layer is deposited to isolate the Back End Of Line (BEOL) process steps from the Front End Of Line (FEOL) process steps. According to the method of the present invention, deposition of this liner layer can be combined with in-situ fluorine doping. Thus, the deposition of the fluorine in-situ doped insulating layer can be integrated into an existing process flow without adding any costs.

The present invention further provides a Metal Oxide Semiconductor Field Effect Transistor (MOSFET) which can be produced in a cost-effective way and which is characterized by an enhanced reliability compared to that of conventional MOSFETs.

According to the present invention the MOSFET comprises a fluorine in-situ doped insulating layer which covers the field effect transistor structure. It has turned out that incorporation of fluorine in the field effect transistor structure reduces the degradation mechanisms thus enhancing the reliability of the transistor.

### BRIEF DESCRIPTION OF THE DRAWINGS

Further features and advantages of the invention read from the following description of embodiments in accordance of the present invention and with reference to the drawings in which:

FIG. 1 shows in a schematic manner a Metal Oxide Semiconductor Field Effect Transistor (MOSFET) manufactured according to a preferred variant of the method according to the present invention;

FIG. 2 shows in a schematic manner selected parts of the MOSFET of FIG. 1;

FIG. 3 shows in a schematic manner the MOSFET of FIG. 2 after diffusion of the fluorine into the field effect transistor structure.

### DETAILED DESCRIPTION OF THE INVENTION

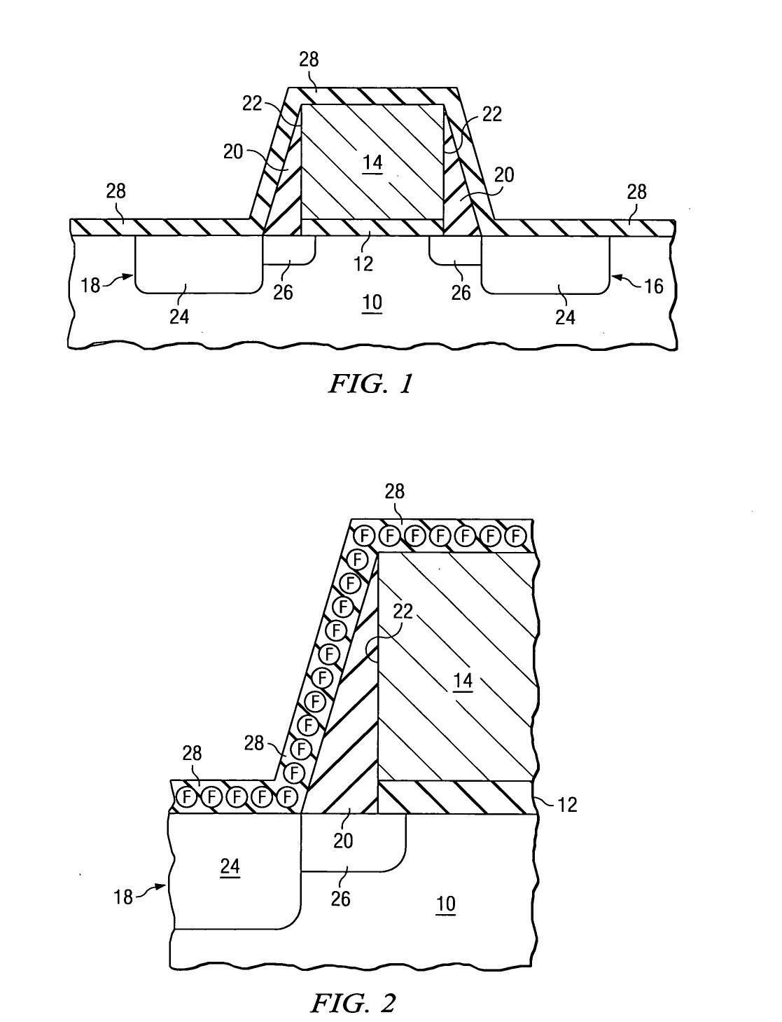

FIG. 1 shows a preferred embodiment of a Metal Oxide Semiconductor Field Effect Transistor (MOSFET) according to the present invention which comprises a semiconductor substrate 10 which can consist, for example, of an epitaxial layer of silicon deposited on a silicon wafer. The MOSFET is, by way of example and without limiting the scope of the present invention, an n-channel MOSFET, so that the epitaxial silicon layer is of p-type. On the silicon substrate 10 a field effect transistor structure is formed which comprises a gate oxide 12, a gate electrode 14 which is formed upon the gate oxide 12 and a drain region 16 and a source region 18 which are each formed on opposite sides and adjacent to the gate electrode 14. The preferred embodiment further comprises a pair of oxide spacers 20 which are disposed at sidewalls 22 of the gate electrode 14. The drain and source regions 16 and 18 are each divided into a heavily doped region 24 and a lightly doped region 26, wherein the lightly doped regions 26 are formed underneath the oxide spacers 20. The field effect transistor structure is covered by a fluorine in-situ doped insulating layer 28.

A standard process flow for forming the field effect transistor structure is described by way of example and without limiting the scope of the present invention:

In case that the MOSFET shown in FIG. 1 of the drawings is part of a CMOS (Complementary Metal Oxide Semiconductor), and the two MOS device types, NMOS and PMOS, are fabricated in the same silicon substrate 10, a so-called well must be created in which to build one type of MOS device while the substrate material is used for building the other MOS device. If the NMOS device type is chosen to be built in a well, a p-well is created to provide a region for the NMOS device, and vice versa, if the PMOS device is chosen to be built in a well, an n-well is created to provide a region for the PMOS device. Thus, the MOSFET shown in the drawings is the MOS device which is built on the substrate material.

After creating the well, a pad of thick oxide is thermally grown on the silicon surface to isolate the PMOS and NMOS parts of the CMOS structure. This process step is called Local Oxidation Of Silicon (LOCOS). Silicon nitride is used as a mask during LOCOS and oxide grows in those areas which are not protected by the silicon nitride. This pad of thick oxide is not shown in the drawings.

After the Local Oxidation Of Silicon, a layer of highest quality gate oxide 12 is grown, followed by the deposition of a polysilicon layer covering the gate oxide layer, e.g. by means of Low Pressure Chemical Vapor Deposition (LPCVD), and by the deposition of a silicide layer, e.g. also by means of LPCVD. The polysilicon layer and the silicide layer are deposited for forming the gate electrodes 14. The gate electrodes 14 are defined by anisotropic plasma etching of the polysilicon and the silicide. To define the source and drain regions 16, 18, several masking and implanting steps are provided subsequent to the above-described defining of the gate electrodes 14.

The oxide spacers 20 disposed at the sidewalls 22 of the gate electrodes 14 are preferably created by depositing a TEOS (Tetraethyl Orthosilicate) oxide and by subsequent anisotropic etching of the TEOS oxide. Several implanting and masking steps are followed for creating the lightly doped source and drain regions 26.

The above-described process steps are well-known from the prior art and hence have been only described in short terms and by way of example.

The above-described Front End Of Line (FEOL) process steps are terminated by depositing the insulating layer 28, e.g. a TEOS layer or a silicon nitride layer. In standard process flows this insulating layer is undoped. According to the present invention, a fluorine in-situ doped insulating layer 28 is deposited which covers the field effect transistor structure or structures (in case of a CMOS process).

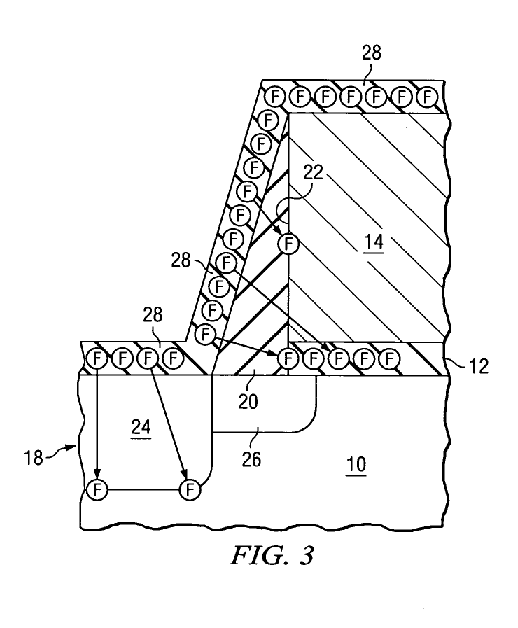

Subsequent thermal heating makes the fluorine diffuse from the insulating layer 28 into the field effect transistor structure, as can be seen in FIG. 3 of the drawings. The fluorine diffuses into the gate oxide 12 and to the interface delimiting the gate oxide 12 from the semiconductor substrate 10. The fluorine also diffuses to the interface delimiting the source/drain region 16, 18 from the semiconductor substrate 10.

The fluorine in the insulating layer 28 is provided for improving the reliability of the fabricated MOSFET by reducing the degradation mechanisms leading to the reduced reliability.

One of these degradation mechanisms is the so-called Hot Carrier Effect (HCE) which is caused by the high electric field in the depletion region of a MOSFET close to the drain edge. Electrons moving along the surface channel are injected into the drain depletion region and are accelerated by the electric field, thus gaining kinetic energy. Some of this energy is lost through collisions with the lattice, producing hole-electron pairs. This process is called impact ionisation. One result of the impact ionisation is an increase in substrate current from the hole-electron pairs generated by the collisions. These collisions also randomise the direction of electrons in the depletion region. Those electrons with high enough energy (hot electrons) and the proper direction are injected into the gate oxide. Some of the injected electrons will remain in the oxide as immobile negative charge. This immobile charge changes the charge distribution in the oxide and causes a threshold voltage shift in the depletion region close to the drain edge. Another mechanism leading to charge trapping in the oxide is the direct tunneling of hot electrons into localized trap levels in the silicon dioxide near the interface. These traps, once filled with immobile negative charges, result in additional threshold voltage shifts. The hot electrons may also damage the substrate-gate oxide interface by creating interface traps which shift the threshold voltage and degrade the electron mobility, e.g. the electrons can break Si—H bonds at the interface thus creating silicon dangling bonds.

The number of hot electrons produced and the resulting threshold voltage shift are maximized under conditions causing a high electric field in the depletion region close to the drain edge, e.g. by a decrease of the channel length while maintaining constant the drain/source voltage and/or by thinning of the gate oxide.

A further, well-known degradation mechanism reducing the reliability of the transistor is the so-called Bias Temperature Instability (BTI). The application of a gate voltage over a relatively long time period at elevated temperatures (Bias Temperature Stressing, BTS) induces the degradation of the transistor parameters such as a threshold voltage shift due to the creation of fixed oxide charges and interface traps.

One approach used to minimize these threshold voltage shifts is to ensure that the electric field in the drain depletion region remains below the critical value. This can be achieved by means of the lightly doped drain/source regions underneath the oxide spacers. By reducing the concentration profile in the vicinity of the drain/source edge which is accomplished by making the source/drain implant a two step process, the electric field near the drain edge is reduced. This lower electric field reduces the incident of hot carrier generation. Another approach to reduce threshold voltage shifts is to reduce the density of traps in the oxide.

The present invention is based on the idea that the fluorine which diffuses from the insulator layer 28 into the field effect transistor structure reduces these degradation mechanisms. The diffused fluorine may interact with the silicon dangling bonds at the gate oxide-silicon substrate interface thus forming Si—F bonds. As Si—F bonds are more robust than Si—H bonds which usually exist at the gate oxide-silicon substrate interface, hot electrons from the channel region which overcome the potential barrier to the gate oxide do not break these Si—F bonds which would result in undesired interface states causing threshold voltage shifts. The fluorine diffused into the gate oxide may also interact with unwanted fixed charges in the gate oxide and gate oxide-substrate interface traps which also cause a threshold voltage shift.

Since the fluorine is in-situ incorporated into the insulating layer during the deposition of this layer, the diffusion of the fluorine from the insulating layer 28 into the field effect transistor structure is already initiated at low temperatures which are normally used in the early process steps of the Back End Of Line (BEOL) process flow. Thus, the problem which is inherent to the methods using implanting of fluorine that subsequent annealing at high temperatures has a negative impact on existing structures, does no longer exist and the deposition of the fluorine in-situ doped layer can be implemented in a late stage of the process flow. Furthermore, deposition of the fluorine in-situ doped layer can be made by using conventional deposition tools, e.g. by using a CVD (Chemical Vapor Deposition) reactor. Preferably, the deposition of the fluorine in-situ doped insulating layer is combined with the deposition of an insulating liner layer for isolating the BEOL process flow from the FEOL process flow thus integrating the deposition of the fluorine doped layer into an existing process flow. Due to all these facts the present invention provides a method for improving the reliability of the fabricated MOSFET without adding any costs or production risks.

1. A method of fabricating a Metal Oxide Semiconductor Field Effect Transistor (MOSFET), comprising the steps of
forming upon a semiconductor substrate a field effect transistor structure comprising a gate oxide, a gate electrode formed upon said gate oxide, a drain region and a source region which are formed within said semiconductor substrate adjacent to said gate electrode, and
depositing a fluorine in-situ doped insulating layer covering said field effect transistor structure.

2. The method of claim 1, wherein depositing of said fluorine in-situ doped layer terminates a sequence of Front End Of Line (FEOL) process steps.

3. The method of claim 1, wherein depositing of said fluorine in-situ doped insulating layer is followed by thermal heating of said insulating layer which makes fluorine diffuse from said insulating layer into said field effect transistor structure.

4. The method of claim 3, wherein said subsequent thermal heating is made during an early process step of a sequence of Back End Of Line (BEOS) process steps.

5. The method of claim 3, wherein said fluorine diffuses into said gate oxide.

6. The method of claim 3, wherein said fluorine diffuses to an interface delimiting said semiconductor substrate from said gate oxide.

7. The method of claim 3, wherein said fluorine diffuses to an interface delimiting said source region from a region of said semiconductor substrate which is not part of said source region.

8. The method of claim 1, further comprising the step of forming at least one oxide spacer disposed on one of the sidewalls of said gate electrode prior to the deposition of said fluorine in-situ doped insulating layer.

9. The method of claim 1, wherein said insulating layer is a fluorine in-situ doped TEOS (Tetraethyl Orthosilicate) layer.

10. The method of claim 1, wherein said insulating layer is a fluorine in-situ doped silicon nitride layer.

11. A Metal Oxide Semiconductor Field Effect Transistor (MOSFET), comprising:
a semiconductor substrate and a field effect transistor structure formed upon said semiconductor substrate, said field effect transistor structure comprising a gate oxide, a gate electrode formed upon said gate oxide, a drain region and a source region, said drain and source regions being formed within said semiconductor substrate adjacent to said gate electrode, and
a fluorine in-situ doped insulating layer covering said field effect transistor structure.

12. The transistor as set forth in claim 10 wherein said insulating layer is a fluorine in-situ doped TEOS (Tetraethyl Orthosilicate) layer.

13. The transistor as set forth in claim 10 wherein said insulating layer is a fluorine in-situ doped silicon nitride layer.
